(19) United States
(12) Patent Application Publication
(10) Pub. No.: US 2026/0242662 A1
(43) Pub. Date: Aug. 20, 2026

(54) CHEMICAL LIQUID AND TREATMENT METHOD

(71) Applicant: FUJIFILM CORPORATION, Tokyo (JP)

(72) Inventor: Shota Oi, Shizuoka (JP)

(21) Appl. No.: 19/058,795

(22) Filed: Feb. 20, 2025

(51) Int. Cl. C09K 13/08; C09K 13/00; H01L 21/306

(52) U.S. Cl. CPC C09K 13/08; C09K 13/00; H10P 50/642

(57) ABSTRACT

An object of the present invention is to provide a chemical liquid which is excellent in removability of SiGe and suppression of surface roughness of Ge in a case of being applied to an object to be treated containing Ge and SiGe. The chemical liquid of the present invention contains an aromatic compound represented by Formula (1), a quinone compound having a quinone structure, a halide ion source, and a solvent.

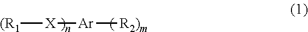

In Formula (1), Ar represents an aromatic ring, X's each independently represent a Group 16 element and R₁'s each independently represent a hydrogen atom or a substituent, n represents an integer of 2 or more, R₂'s each independently represent a substituent, and m represents an integer of 0 or more.

### CROSS-REFERENCE TO RELATED APPLICATIONS

This application is a Continuation of PCT International Application No. PCT/JP2023/031582 filed on Aug. 30, 2023, which claims priority under 35 U.S.C. § 119 (a) to Japanese Patent Application No. 2022-150022 filed on Sep. 21, 2022. The above applications are hereby expressly incorporated by reference, in their entirety, into the present application.

### BACKGROUND OF THE INVENTION

### 1. Field of the Invention

The present invention relates to a chemical liquid and a treatment method.

### 2. Description of the Related Art

In a case of forming circuits and elements, it is common to carry out an etching process using a chemical liquid. In this case, since a plurality of materials may be present on a substrate, it is desirable that the chemical liquid used for the etching is capable of selectively removing only a specific material.

For example, JP2019-165218A discloses an etching solution (chemical liquid) suitable for selectively removing a silicon-germanium alloy rather than germanium from a microelectronics device. Specifically, an etching solution (chemical liquid) containing water, an oxidizing agent (quinone), a fluoride ion source, and a corrosion inhibitor is disclosed.

### SUMMARY OF THE INVENTION

Examples of an object to be treated with the chemical liquid include an object to be treated containing germanium (hereinafter, also simply referred to as “Ge”) and silicon-germanium (hereinafter, also simply referred to as “SiGe”), as disclosed in JP2019-165218A.

In a case of treating the object to be treated containing Ge and SiGe as described above, it is required that removability of SiGe is excellent, and in recent years, it has been required to improve the removability. In addition, in a case of treating the object to be treated as described above, it is also required to suppress surface roughness of Ge contained in the object to be treated.

The present inventors have found that, in a case where the object to be treated containing Ge and SiGe is treated using the chemical liquid disclosed in JP2019-165218A, both the removability of SiGe and the suppression of surface roughness of Ge cannot be achieved, and there is room for improvement.

An object of the present invention is to provide a chemical liquid which is excellent in removability of SiGe and suppression of surface roughness of Ge in a case of being applied to an object to be treated containing Ge and SiGe.

Another object of the present invention is to provide a treatment method of an object to be treated.

The present inventors have completed the present invention as a result of intensive studies to solve the above-described problems. That is, the present inventors have found that the above-described objects can be achieved by the following configuration.
[1] A chemical liquid comprising:
an aromatic compound represented by Formula (1) described later;
a quinone compound having a quinone structure;
a halide ion source; and
a solvent.
[2] The chemical liquid according to [1],
in which a content of the aromatic compound is 5 ppb by mass to 1% by mass with respect to a total mass of the chemical liquid.
[3] The chemical liquid according to [1] or [2],
in which Ar in Formula (1) is a benzene ring, a naphthalene ring, or an anthracene ring.
[4] The chemical liquid according to [3],
in which any one of the following requirements 1 to 4 is satisfied,
requirement 1: n in Formula (1) is 2, R₁ represents a hydrogen atom, Ar in Formula (1) represents a benzene ring, and bonding positions of two groups represented by —X—R₁ are a 1-position and a 4-position of the benzene ring,
requirement 2: n in Formula (1) is 2, R₁ represents a hydrogen atom, Ar in Formula (1) represents a naphthalene ring, and bonding positions of two groups represented by —X—R₁ are a 1-position and a 4-position of the naphthalene ring,
requirement 3: n in Formula (1) is 2, Ar in Formula (1) represents an anthracene ring, and bonding positions of two groups represented by —X—R₁ are a 9-position and a 10-position of the anthracene ring,
requirement 4: n in Formula (1) is 4, Ar in Formula (1) represents an anthracene ring, and bonding positions of four groups represented by —X—R₁ are a 1-position, a 4-position, a 9-position, and a 10-position of the anthracene ring.
[5] The chemical liquid according to any one of [1] to [4],
in which X's in Formula (1) are each independently an oxygen atom or a sulfur atom.
[6] The chemical liquid according to any one of [1] to [5],
in which the aromatic compound is a compound represented by Formula (2) described later.
[7] The chemical liquid according to [6],
in which, in Formula (2), X₁ and X₂ represent oxygen atoms and R₃ and R₄ represent hydrogen atoms.
[8] The chemical liquid according to any one of [1] to [7],
in which the halide ion source includes hydrogen fluoride.
[9] The chemical liquid according to [8],
in which a content of the hydrogen fluoride is 0.01% to 10% by mass with respect to a total mass of the chemical liquid.
[10] The chemical liquid according to any one of [1] to [9],
in which a ratio of a content of the quinone compound to a content of the aromatic compound is 10.0 to 200.0.
[11] The chemical liquid according to any one of [1] to [10],
in which the solvent includes one or more solvents selected from the group consisting of water, an alcohol solvent, an ether solvent, an ester solvent, an amide solvent, and a sulfoxide solvent.
[12] The chemical liquid according to any one of [1] to [11],
in which the chemical liquid is applied to an object to be treated containing germanium and silicon-germanium.
[13] A treatment method of an object to be treated, comprising:
a step of bringing the chemical liquid according to any one of [1] to into contact with an object to be treated containing germanium and silicon-germanium.

According to the present invention, it is possible to provide a chemical liquid which is excellent in removability of SiGe and suppression of surface roughness of Ge in a case of being applied to an object to be treated containing Ge and SiGe.

In addition, according to the present invention, it is possible to provide a treatment method of an object to be treated.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Hereinafter, meaning of each description in the present specification will be explained.

In the present specification, a numerical range represented by “to” means a range including numerical values before and after “to” as a lower limit value and an upper limit value.

In the present specification, “ppm” is an abbreviation for “parts per million” and means 10⁻⁶. In addition, “ppb” is an abbreviation for “parts per billion” and means 10⁻⁹. “ppt” is an abbreviation for “parts per trillion” and means 10⁻¹².

In the present specification, in a case where there are two or more components corresponding to a certain component, “content” of such a component means the total content of the two or more components.

In the present specification, “germanium” refers to a material substantially composed of only a Ge element. The “substantially” means that a content of the Ge element is 90 atom % or more with respect to all atoms of the material. Therefore, other elements (excluding an Si element) may be contained as long as the content of the Ge element is within the above-described range.

In addition, in the present specification, “silicon-germanium” refers to a material substantially composed of only an Si element and a Ge element. The “substantially” means that the total content of the Si element and the Ge element is 90 atom % or more with respect to all atoms of the material. Therefore, other elements may be contained as long as the total content of the Si element and the Ge element is within the above-described range. In addition, in the silicon-germanium, a content ratio of the Si element and the Ge element is not particularly limited, and a proportion of the content of the Ge element to the total amount of the Si element and the Ge element is preferably 30 to 80 atom %.

Unless otherwise specified, “exposure” includes exposure with a mercury lamp, a far ultraviolet ray represented by an excimer laser, an X-ray, or EUV light, and drawing with a corpuscular beam such as an electron beam and an ion beam.

“Preparation” includes not only providing a specific material by synthesis, formulation, or the like, but also procuring a predetermined item by purchase or the like.

With regard to a bonding direction of a divalent group (for example, —COO—), unless otherwise specified, in a case where Y in a compound represented by “X-Y-Z” is —COO—, the compound may be “X—O—CO—Z” or “X—CO—O—Z”.

### <Chemical Liquid>

The chemical liquid according to the embodiment of the present invention contains an aromatic compound represented by Formula (1) described later, a quinone compound having a quinone structure, a halide ion source, and a solvent.

In a case where an object to be treated containing Ge and SiGe is treated using the chemical liquid according to the embodiment of the present invention, a mechanism by which removability of SiGe is excellent and surface roughness of Ge is suppressed is not always clear, but the present inventors have presumed as follows.

The chemical liquid according to the embodiment of the present invention exhibits an etching ability of SiGe by containing the quinone compound, the halide ion source, and the solvent. Furthermore, since the chemical liquid according to the embodiment of the present invention contains the aromatic compound, it is considered that the aromatic compound and the quinone compound act synergistically on residue of SiGe which has not been completely etched, and thus the removability of SiGe is excellent.

In addition, it is considered that the aromatic compound has a higher affinity for Ge than for SiGe, and the aromatic compound is likely to be collected in the vicinity of the surface of Ge. It is considered that the aromatic compound present in the vicinity of the surface of Ge synergistically acts with the quinone compound, and as a result, the surface roughness of Ge is suppressed.

Hereinafter, the components contained in the chemical liquid will be described.

### [Aromatic Compound]

The chemical liquid according to the embodiment of the present invention contains an aromatic compound represented by Formula (1).

Hereinafter, each symbol in Formula (1) will be described.

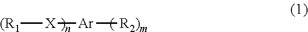

In Formula (1), Ar represents an aromatic ring.

The aromatic ring represented by Ar may have a monocyclic structure or a polycyclic structure.

The aromatic ring represented by Ar may include a heteroatom other than carbon atoms. Examples of the heteroatom include a nitrogen atom, an oxygen atom, and a sulfur atom. It is also preferable that the aromatic ring represented by Ar does not include the heteroatom.

Examples of the aromatic ring represented by Ar include a benzene ring, a pyridine ring, a naphthalene ring, an anthracene ring, a phenanthrene ring, and a pyrene ring; and a benzene ring, a naphthalene ring, or an anthracene ring is preferable, and a benzene ring is more preferable.

In Formula (1), X's each independently represent a Group 16 element, and R₁'s each independently represent a hydrogen atom or a substituent. That is, as will be described later, since n is 2 or more, two or more X's may be the same or different from each other, and two or more R₁'s may be the same or different from each other.

Examples of the Group 16 element represented by X include an oxygen atom, a sulfur atom, a selenium atom, and a tellurium atom; and an oxygen atom or a sulfur atom is preferable, and an oxygen atom is more preferable. In addition, it is preferable that all X's in Formula (1) are oxygen atoms or sulfur atoms, and it is more preferable that all X's in Formula (1) are oxygen atoms.

The type of the substituent represented by R₁ is not particularly limited, and examples thereof include a hydrocarbon group which may have a heteroatom. Among these, an aliphatic hydrocarbon group is preferable, and an alkyl group is more preferable. As the alkyl group, an alkyl group having 1 to 5 carbon atoms is preferable, an alkyl group having 1 to 3 carbon atoms is more preferable, and a methyl group is still more preferable. It is preferable that at least one of R₁'s is a hydrogen atom, and it is more preferable that all R₁'s are hydrogen atoms.

In Formula (1), n represents an integer of 2 or more.

The integer represented by n is preferably 2 to 6, more preferably 2 to 4, and still more preferably 2.

In Formula (1), R₂ represents a substituent.

Examples of the substituent represented by R₂ include an alkyl group and a halogen atom (a fluorine atom, a chlorine atom, a bromine atom, or an iodine atom). The alkyl group represented by R₂ is preferably an alkyl group having 1 to 5 carbon atoms and more preferably an alkyl group having 1 to 3 carbon atoms.

In a case where a plurality of R₂'s are included in Formula (1), the plurality of R₂'s may be different from each other or may be the same as each other.

In Formula (1), m represents an integer of 0 or more.

The integer represented by m is preferably 0 to 4, more preferably 0 to 2, and still more preferably 0.

Two or more groups represented by —X—R₁ may be bonded to any position of the group represented by Ar.

Among these, it is preferable to satisfy any one of the following requirements 1 to 4.

Requirement 1: n is 2, R₁ represents a hydrogen atom, Ar in Formula (1) represents a benzene ring, and bonding positions of two groups represented by —X—R₁ are a 1-position and a 4-position of the benzene ring.

Requirement 2: n is 2, R₁ represents a hydrogen atom, Ar in Formula (1) represents a naphthalene ring, and bonding positions of two groups represented by —X—R₁ are a 1-position and a 4-position of the naphthalene ring.

Requirement 3: n is 2, R₁ represents a hydrogen atom, Ar in Formula (1) represents an anthracene ring, and bonding positions of two groups represented by —X—R₁ are a 9-position and a 10-position of the anthracene ring.

Requirement 4: n is 4, R₁ represents a hydrogen atom, Ar in Formula (1) represents an anthracene ring, and bonding positions of four groups represented by —X—R₁ are a 1-position, a 4-position, a 9-position, and a 10-position of the anthracene ring.

The aromatic compound is preferably an aromatic compound represented by Formula (2).

Hereinafter, each symbol in Formula (2) will be described.

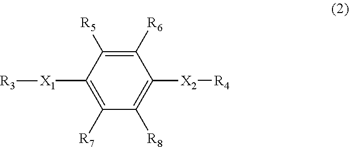

In Formula (2), R₃ and R₄ each independently represent a hydrogen atom or an alkyl group.

The alkyl group represented by R₃ and R₄ is preferably an alkyl group having 1 to 5 carbon atoms, more preferably an alkyl group having 1 to 3 carbon atoms, and still more preferably a methyl group. It is preferable that at least one of R₃ or R₄ is a hydrogen atom, and it is more preferable that R₃ and R₄ are hydrogen atoms.

In Formula (2), X₁ and X₂ each independently represent a Group 16 element.

Examples of the Group 16 element represented by X₁ and X₂ include an oxygen atom, a sulfur atom, a selenium atom, and a tellurium atom; and an oxygen atom or a sulfur atom is preferable, and an oxygen atom is more preferable. In addition, it is preferable that both X₁ and X₂ in Formula (2) are oxygen atoms or sulfur atoms, and it is more preferable that both X₁ and X₂ in Formula (2) are oxygen atoms.

In Formula (2), R₅ to R₈ each independently represent a hydrogen atom or a substituent.

Examples of the substituent represented by R₅ to R₈ include an alkyl group and a halogen atom (a fluorine atom, a chlorine atom, a bromine atom, or an iodine atom). The alkyl group represented by R₅ to R₈ is preferably an alkyl group having 1 to 5 carbon atoms and more preferably an alkyl group having 1 to 3 carbon atoms.

The substituent represented by R₅ and R₆ and the substituent represented by R₇ and R₈ may be bonded to each other to form a ring. The ring to be formed may be an alicyclic ring or an aromatic ring, and an aromatic ring is preferable.

It is also preferable that all of R₅ to R₆ are hydrogen atoms.

Specific examples of the aromatic compound include hydroquinone (1,4-benzenediol), catechol (1,2-benzenediol), resorcinol (1,3-benzenediol), methylhydroquinone, 1,2,4-benzenetriol, 1,3,5-benzenetriol, 1,2,3-benzenetriol, 1,2,3,4-benzenetetraol, 1,2,4,5-benzenetetraol, naphthohydroquinone (1,4-naphthalenediol), 1,5-naphthalenediol, anthrahydroquinone (9,10-anthracenediole), leucoquinizarin (1,4-dihydro-9,10-anthracenediole), 1,4-benzenedithiol, 1,2-benzenedithiol, 1,3-benzenedithiol, 1,4-naphthalenedithiol, 1,5-naphthalenedithiol, 4-hydroxybenzenethiol, mequinol (4-methoxyphenol), 2-methoxyphenol, 4-(methylthio)benzenethiol, 2,3-dihydroxypyridine, 2,4-dihydroxypyridine, and 1,4-benzenediselenol.

Among these, hydroquinone, catechol, naphthohydroquinone, leucoquinizarin, 1,4-benzenedithiol, 1,5-naphthalenedithiol, 4-hydroxybenzenethiol, or 4-(methylthio)benzenethiol is preferable; and hydroquinone, naphthohydroquinone, leucoquinizarin, 1,4-benzenedithiol, or 4-hydroxybenzenethiol is more preferable.

A content of the aromatic compound is preferably 0.1 ppb by mass to 5% by mass, more preferably 5 ppb by mass to 1% by mass, still more preferably 0.001% by mass to 0.5% by mass, and particularly preferably 0.005% by mass to 0.1% by mass with respect to the total mass of the chemical liquid.

The aromatic compound may be used alone or in combination of two or more kinds thereof.

In a case where two or more kinds of the aromatic compounds are used, the total amount thereof is preferably within the above-described preferred content range.

### [Quinone Compound]

The chemical liquid according to the embodiment of the present invention contains a quinone compound having a quinone structure.

The quinone structure refers to a cyclic structure including two carbonyl groups.

The quinone compound may have a monocyclic structure or a polycyclic structure, and a monocyclic structure is preferable. The quinone compound preferably has a carbon atom-carbon atom double bond adjacent to the carbonyl group.

The number of carbon atoms constituting the cyclic structure of the quinone compound is preferably 6 to 15, more preferably 6 to 10, and still more preferably 6. The number of carbon atoms in the quinone compound is preferably 6 to 20, more preferably 6 to 10, and still more preferably 6 to 8.

As the quinone compound, a quinone compound exhibiting an oxidation action is also preferable.

Examples of the quinone compound include p-benzoquinone, o-benzoquinone, 1,4-naphthoquinone, 1,5-naphthoquinone, 1,2-naphthoquinone, 2,6-naphthoquinone, anthraquinone, phenanthrenequinone, acenaphthoquinone, 2,6-dimethyl-1,4-benzoquinone, 2,5-dimethyl-1,4-benzoquinone, trimethyl-1,4-benzoquinone, tetramethyl-1,4-benzoquinone, tetrachloro-1,4-benzoquinone, tetrafluoro-1,4-benzoquinone, 2,5-diphenyl-1,4-benzoquinone, and 2,3-dichloro-5,6-dicyano-p-benzoquinone.

Among these, p-benzoquinone, o-benzoquinone, or 1,4-naphthoquinone is preferable, and p-benzoquinone or o-benzoquinone is more preferable.

A content of the quinone compound is preferably 0.01% to 10% by mass, more preferably 0.05% to 3.0% by mass, and still more preferably 0.1% to 2.0% by mass with respect to the total mass of the chemical liquid.

A ratio of the content of the quinone compound to the content of the aromatic compound is preferably 0.3 to 10000000.0 and more preferably 10.0 to 200.0.

The quinone compound may be used alone or in combination of two or more kinds thereof.

In a case where two or more kinds of the quinone compounds are used, the total amount thereof is preferably within the above-described preferred content range.

In addition, the quinone compound may be present as a tautomer in the chemical liquid.

### [Halide Ion Source]

The chemical liquid according to the embodiment of the present invention contains a halide ion source.

The halide ion source refers to a compound capable of releasing a halide ion or a halogen-containing ion in the chemical liquid. In the chemical liquid according to the embodiment of the present invention, the halide ion source may be a halide ion or a halogen-containing ion.

Examples of the halogen atom contained in the halide ion source include a fluorine atom, a chlorine atom, a bromine atom, and an iodine atom; and a fluorine atom or a chlorine atom is preferable, and a fluorine atom is more preferable. That is, the halide ion source is preferably a fluoride ion source. The fluoride ion source is a compound capable of releasing a fluoride ion (F⁻) or a fluorine-containing ion in the chemical liquid.

Examples of the fluorine-containing ion include a bifuloride ion (HF₂⁻), SiF₆²⁻, TiF₆²⁻, ZrF₆²⁻, PF₆⁻, and BF₄⁻.

The fluoride ion source is usually a salt of a fluoride ion or a fluorine-containing ion and a cation.

Examples of the cation preferably contained in the fluoride ion source include H⁺, Li⁺, Na⁺, K⁺, and NH₄⁺; and H⁺ is preferable.

As the fluoride ion source, hydrogen fluoride (HF), ammonium fluoride (NH₄F), hexafluorosilicic acid (H₂SiF₆), hexafluorosilicic acid (Na₂SiF₆), hexafluorosilicic acid (H₂TiF₆), hexafluorozirconic acid (H₂ZrF₆), hexafluorophosphoric acid (HPF₆), or hexafluorophosphoric acid (HBF₄) is preferable; hydrogen fluoride or ammonium fluoride is more preferable; and hydrogen fluoride is still more preferable.

A content of the halide ion source is preferably 0.004% to 20% by mass, more preferably 0.01% to 10% by mass, still more preferably 0.02% to 10% by mass, and particularly preferably 0.4% to 7.5% by mass with respect to the total mass of the chemical liquid.

The halide ion source may be used alone or in combination of two or more kinds thereof. In a case where two or more kinds of the halide ion sources are used, the total amount thereof is preferably within the above-described preferred content range.

A solution may be used as the halide ion source. In a case where the halide ion source is a solution, the content of the halide ion source is a content of the fluoride ion source contained in the solution.

### [Solvent]

The chemical liquid according to the embodiment of the present invention contains a solvent.

The solvent is not particularly limited; but is preferably one or more solvents selected from the group consisting of water, an alcohol solvent, an ether solvent, an ester solvent, an amide solvent, and a sulfoxide solvent, and more preferably one or more solvents selected from the group consisting of water, an alcohol solvent, an ether solvent, and a sulfoxide solvent.

It is also preferable that the solvent is mixed with water at an optional ratio.

Examples of the alcohol solvent include methanol, ethanol, 1-propanol, 2-propanol, 1-butanol, 2-butanol, ethylene glycol, propylene glycol, glycerin, 1,6-hexanediol, cyclohexanediol, sorbitol, xylitol, 2-methyl-2,4-pentanediol, 1,3-butanediol, and 1,4-butanediol.

The number of carbon atoms in the alcohol solvent is preferably 1 to 8 and more preferably 1 to 4.

Examples of the ether solvent include diethyl ether, diisopropyl ether, dibutyl ether, t-butyl methyl ether, cyclohexyl methyl ether, tetrahydrofuran, diethylene glycol, dipropylene glycol, triethylene glycol, polyethylene glycol, alkylene glycol monoalkyl ether (ethylene glycol monomethyl ether, ethylene glycol monobutyl ether, propylene glycol monomethyl ether, diethylene glycol monomethyl ether, dipropylene glycol monomethyl ether, tripropylene glycol monomethyl ether, and diethylene glycol monobutyl ether), and alkylene glycol dialkyl ether (diethylene glycol diethyl ether, diethylene glycol dipropyl ether, diethylene glycol dibutyl ether, triethylene glycol diethyl ether, tetraethylene glycol dimethyl ether, tetraethylene glycol diethyl ether, ethylene glycol dimethyl ether, diethylene glycol dimethyl ether, and triethylene glycol dimethyl ether).

The number of carbon atoms in the ether solvent is preferably 3 to 16 and more preferably 4 to 14.

Examples of the ester solvent include methyl acetate, ethyl acetate, butyl acetate, isobutyl acetate, methyl lactate, ethyl lactate, and butyl lactate.

Examples of the amide solvent include formamide, monomethylformamide, dimethylformamide, acetamide, monomethylacetamide, dimethylacetamide, monoethylacetamide, diethylacetamide, and N-methylpyrrolidone.

Examples of the sulfoxide solvent include dimethyl sulfoxide.

A content of the solvent is preferably 60% to 99.99% by mass and more preferably 80% to 99.9% by mass with respect to the total mass of the chemical liquid.

The solvent may be used alone or in combination of two or more kinds thereof.

In a case where two or more kinds of the solvents are used, the total amount thereof is preferably within the above-described preferred content range.

### [Optional Component]

The chemical liquid may contain an optional component in addition to the above-described components.

Hereinafter, components which can be contained in the chemical liquid will be described.

### (Basic Compound)

The chemical liquid may contain a basic compound.

The basic compound is a compound which exhibits alkalinity (a pH of more than 7.0) in an aqueous solution.

Examples of the basic compound include an organic base, an inorganic base, and a salt of these bases.

Examples of the organic base include a quaternary ammonium salt, an alkylamine compound or a salt thereof, an amine oxide compound, a nitro compound, a nitroso compound, an oxime compound, a ketoxime compound, an aldoxime compound, a lactam compound, and an isocyanide compound.

As the alkylamine compound, a trialkylamine compound is preferable. An alkyl group moiety of the alkylamine compound may have a substituent, and the substituent is not particularly limited and examples thereof include a hydroxy group and a phenyl group. A methylene group constituting the above-described alkyl group moiety may be substituted with a divalent linking group such as —O—. In addition, the above-described alkyl group moieties may be bonded to each other to form a ring.

Specific examples of the trialkylamine compound include methylamine, ethylamine, dimethylamine, diethylamine, trimethylamine, triethylamine, N-methyldiethanolamine, N-ethyldiethanolamine, N,N-dimethylethanolamine, N-methylmorpholine, N-ethylmorpholine, and a salt thereof.

Examples of the inorganic base include alkali metal hydroxides such as sodium hydroxide and potassium hydroxide, alkaline earth metal hydroxides, and ammonia or a salt thereof.

A content of the basic compound is not particularly limited, but is preferably 0.1% by mass or more and more preferably 0.5% by mass or more with respect to the total mass of the chemical liquid. The upper limit thereof is not particularly limited, but is preferably 20.0% by mass or less with respect to the total mass of the chemical liquid.

### (Acidic Compound)

The chemical liquid may contain an acidic compound.

The acidic compound is an acidic compound which exhibits acidity (a pH of less than 7.0) in an aqueous solution.

Examples of the acidic compound include an inorganic acid, an organic acid, and a salt thereof.

However, the acidic compound is a compound different from the above-described halide ion source.

Examples of the inorganic acid include sulfuric acid, phosphoric acid, nitric acid, and a salt thereof.

Examples of the organic acid include carboxylic acid, sulfonic acid, and a salt thereof.

Examples of the carboxylic acid include lower (1 to 4 carbon atoms) aliphatic monocarboxylic acids such as formic acid, acetic acid, propionic acid, and butyric acid, and a salt thereof.

Examples of the sulfonic acid include methanesulfonic acid, benzenesulfonic acid, p-toluenesulfonic acid (tosylic acid), and a salt thereof.

A content of the acidic compound is not particularly limited, but is preferably 0.1% by mass or more and more preferably 0.5% by mass or more with respect to the total mass of the chemical liquid. The upper limit thereof is not particularly limited, but is preferably 20.0% by mass or less with respect to the total mass of the chemical liquid.

### (Surfactant)

The chemical liquid may contain a surfactant.

The surfactant is not particularly limited as long as it is a compound having a hydrophilic group and a hydrophobic group (lipophilic group) in one molecule, and examples thereof include an anionic surfactant, a cationic surfactant, and a nonionic surfactant.

Examples of the hydrophobic group included in the surfactant include an aliphatic hydrocarbon group, an aromatic hydrocarbon group, and a combination thereof.

In a case where the hydrophobic group includes an aromatic hydrocarbon group, the number of carbon atoms in the hydrophobic group is preferably 6 or more and more preferably 10 or more.

In a case where the hydrophobic group does not include an aromatic hydrocarbon group and is composed of only an aliphatic hydrocarbon group, the number of carbon atoms in the hydrophobic group is preferably 8 or more and more preferably 10 or more. The upper limit of the number of carbon atoms in the hydrophobic group is not particularly limited, but is preferably 24 or less and more preferably 20 or less.

A content of the surfactant is not particularly limited, but is preferably 10 ppm by mass or more and more preferably 30 ppm by mass or more with respect to the total mass of the chemical liquid. The upper limit thereof is not particularly limited, but from the viewpoint of suppressing foaming of the chemical liquid, it is preferably 10% by mass or less and more preferably 5% by mass or less with respect to the total mass of the chemical liquid.

### (Anticorrosion Agent)

The chemical liquid may contain an anticorrosion agent.

The anticorrosion agent is added to the chemical liquid for the purpose of preventing etching of other materials present on the object to be treated, which will be described later.

However, the anticorrosion agent does not include the above-described aromatic compound.

The type of the anticorrosion agent is appropriately selected depending on the material type of the other materials present on the object to be treated.

Examples of the anticorrosion agent include an amine compound, an imine compound, a thiol compound, and a thioether compound. Among these, an imine compound is preferable, and a nitrogen-containing unsaturated heterocyclic compound is more preferable.

Examples of the nitrogen-containing unsaturated heterocyclic compound include pyridine, triazine, imidazole, benzimidazole, purine, xanthine, and a derivative thereof.

A content of the anticorrosion agent is not particularly limited, but is preferably 0.1% by mass or more and more preferably 1% by mass or more with respect to the total mass of the chemical liquid. The upper limit thereof is not particularly limited, but is preferably 10% by mass or less and more preferably 5% by mass or less with respect to the total mass of the chemical liquid.

### (Insoluble Particles)

It is preferable that the chemical liquid according to the embodiment of the present invention does not substantially contain insoluble particles.

The “insoluble particles” are particles of an inorganic solid, an organic solid, and the like, and correspond to particles which are present as particles without being finally dissolved in the chemical liquid.

The expression “does not substantially contain insoluble particles” means that the number of particles having a particle diameter of 50 nm or more, contained in 1 mL of a composition for measurement, is 40,000 or less in a case where the chemical liquid is diluted 10,000 times with the solvent contained in the chemical liquid to obtain the composition for measurement. The number of the particles contained in the composition for measurement can be measured in a liquid phase using a commercially available particle counter.

As a commercially available particle counter device, a device manufactured by RION Co., Ltd. or a device manufactured by PMS Co., Ltd. can be used. Representative examples of the device of the former include KS-19F, and representative examples of the device of the latter include Chem20. In order to measure larger particles, a device such as KS-42 series or LiQuilaz II S series can be used.

Examples of the insoluble particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

Examples of a method for removing the insoluble particles from the chemical liquid include a purification treatment such as filtering.

### [Physical Properties of Chemical Liquid]

### (Coarse Particles)

The chemical liquid may contain coarse particles, but it is preferable that a content thereof is low.

The coarse particles mean particles having a diameter (particle size) of 1 μm or more, in a case where a shape of the particles is regarded as a sphere. The particles included in the above-described insoluble particles may be included in the coarse particles.

A content of the coarse particles in the chemical liquid, in terms of content of particles having a particle size of 1 μm or more, is preferably 100 or less and more preferably 50 or less per 1 mL of the chemical liquid. The lower limit thereof is preferably 0 or more, and more preferably 0.01 or more per 1 mL of the chemical liquid.

The coarse particles contained in the chemical liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the chemical liquid, in which those particles are finally present as particles without being dissolved in the chemical liquid.

The content of the coarse particles present in the chemical liquid can be measured in a liquid phase by using a commercially available measuring device in a light scattering type liquid particle measuring method using a laser as a light source.

Examples of a method for removing the coarse particles include a purification treatment such as filtering, which will be described later.

### <Method for Producing Chemical Liquid>

The chemical liquid can be produced by a known method. Hereinafter, a method for producing the chemical liquid will be described in detail.

### [Liquid Preparation Step]

The chemical liquid can be produced, for example, by mixing the above-described components.

The order and/or timing of mixing the above-described components is not particularly limited, and examples thereof include a method in which the aromatic compound, the quinone compound, and the halide ion source are sequentially charged into a container containing a purified solvent (for example, ethanol), and then the mixture is stirred and mixed. In addition, a pH adjuster may be added thereto to adjust the pH of the mixed solution, thereby preparing a liquid. In addition, in a case where the solvent and the components are charged into the container, the solvent and the components may be charged at once, or may be charged in a divided manner a plurality of times.

As a stirring device and a stirring method used for preparing the chemical liquid, a known device may be used as a stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the components in the step of preparing the chemical liquid, a refining treatment described later, and storage of the produced chemical liquid are preferably performed at 40° C. or lower, and more preferably performed at 30° C. or lower. In addition, the lower limit thereof is preferably 5° C. or higher, and more preferably 10° C. or higher. By performing the preparation of the chemical liquid, the treatment, and/or the storage of the chemical liquid in the above-described temperature ranges, the performance can be stably maintained for a long period of time.

### [Dilution Step]

The chemical liquid may be used as a diluted chemical liquid (diluted liquid chemical) after undergoing a dilution step of diluting the chemical liquid using a diluent.

The diluted chemical liquid is also a form of the chemical liquid according to the embodiment of the present invention as long as the requirements of the present invention are satisfied.

Examples of the diluted liquid include a solvent and an aqueous solution including isopropanolamine (1-amino-2-propanol) or ammonia.

It is preferable to subject the diluted liquid which is used in the dilution step to a purification treatment in advance. In addition, it is more preferable that the diluted chemical liquid obtained in the dilution step is subjected to a purification treatment.

Examples of the purification treatment include an ion component reducing treatment using an ion exchange resin, an RO membrane, or the like, and a foreign matter removal using filtering described as the purification treatment for the chemical liquid above, and it is preferable to carry out any of these treatments.

A dilution rate of the chemical liquid in the dilution step may be appropriately adjusted according to the type and content of each component, and the use target and purpose of the chemical liquid. A ratio (dilution ratio) of the diluted chemical liquid to the chemical liquid before the dilution in terms of mass ratio or volume ratio (volume ratio at 23° C.) is preferably 1.5 to 10,000 times, more preferably 2 to 2,000 times, and still more preferably 50 to 1,000 times.

In addition, it is also possible for the chemical liquid (diluted chemical liquid) to be suitably put to practical use, the chemical liquid containing components in amounts obtained by dividing the suitable contents of components (excluding the solvent) contained in the above-described chemical liquid by the dilution factor (for example, 100) in the above-described range.

In other words, the suitable content of each component (excluding the solvent) with respect to the total mass of the diluted chemical liquid is an amount obtained, for example, by dividing the amount described as the suitable content of each component with respect to the total mass of the chemical liquid (chemical liquid before the dilution) by the dilution ratio in the above-described range (for example, 100).

A change in pH before and after the dilution (a difference between the pH of the chemical liquid before the dilution and the pH of the diluted chemical liquid) is preferably 2.0 or less, more preferably 1.8 or less, and still more preferably 1.5 or less.

It is preferable that the pH of the chemical liquid before the dilution and the pH of the diluted chemical liquid are each in the above-described suitable aspect.

Specific methods of the dilution step of diluting the chemical liquid may be performed based on the step of preparing the chemical liquid as described above. A stirring device and a stirring method used in the dilution step may also be performed using the known stirring device described in the step of preparing the chemical liquid above.

### <Applications of Chemical Liquid>

The chemical liquid is preferably used for manufacturing a semiconductor. More specifically, the chemical liquid is preferably used for manufacturing a semiconductor element.

The chemical liquid can also be used in a process of manufacturing a semiconductor element, and can be used, for example, for treating a material composed of germanium, an insulating film, a resist film, an antireflection film, an etching residue, and an ashing residue (hereinafter, also simply referred to as “residue”) present on a substrate. The chemical liquid may also be used for treating a substrate after chemical mechanical polishing.

In particular, the chemical liquid is preferably used for treating an object to be treated containing Ge and SiGe (hereinafter, also simply referred to as “object to be treated”). Preferred examples of the element obtained by treating the object to be treated with the chemical liquid include a field effect transistor (FET), and more preferred examples thereof include a gate-all-around field effect transistor (GAA-FET). That is, the chemical liquid is preferably used in a manufacturing process of the GAA-FET.

The GAA-FET refers to an FET having a structure in which a side surface portion of a channel between a drain and a source is covered with a gate over the entire circumference. Examples of the channel in the GAA-FET include an aspect in which the channel includes a nano-sized wire-like member. In the manufacturing of the GAA-FET, for example, a process of selectively removing SiGe from an object to be treated having a nanostructure is included, and the chemical liquid of the present invention can be preferably used in the process.

More specifically, first, an SiGe layer and a Ge layer are alternately deposited on a silicon wafer by heteroepitaxy. Hereinafter, the SiGe layer and the Ge layer which are alternately laminated are also simply referred to as “SiGe layer-Ge layer laminated film”.

Examples of the configuration of the SiGe layer-Ge layer laminated film include a configuration in which a thick (for example, 50 nm or more) SiGe layer (Si:Ge=70:30 (atomic number ratio)) is formed, and then an SiGe layer (Si:Ge=65:33 (atomic number ratio)) and a Ge layer, having a film thickness of 10 nm, are alternately laminated.

Next, a hard mask of silicon oxide and a hard mask of silicon nitride are formed in this order on the SiGe layer-Ge layer laminated film, the hard masks are processed into a desired shape, and the SiGe layer-Ge layer laminated film is processed along the shape of the hard masks. The shape to be processed can be appropriately selected, and for example, the SiGe layer-Ge layer laminated film can be processed into a fin shape. In the SiGe layer-Ge layer laminated film after the processing, the SiGe layer and the Ge layer are exposed in a cross section.

In a case where the silicon wafer on which the above-described structure body is formed is used as the object to be treated and treated with the chemical liquid according to the embodiment of the present invention, the SiGe layer is selectively etched, and a nanowire-like Ge can be formed.

### <Treatment Method of Object to be Treated>

Hereinafter, a treatment method of an object to be treated, containing Ge and SiGe, using the chemical liquid according to the embodiment of the present invention will be described.

### [Object to be Treated]

The object to be treated contains Ge and SiGe.

The object to be treated is not particularly limited as long as it contains Ge and SiGe, but generally, Ge and SiGe are arranged on a substrate.

Here, the expression “on the substrate” includes any aspect of front and back surfaces, side surfaces, or inside of grooves of the substrate.

In addition, the expression “Ge and SiGe are arranged on a substrate” also includes a case where Ge and SiGe are directly present on the surface of the substrate and a case where Ge and SiGe are present on the substrate through another layer.

In addition, the expression “Ge and SiGe are arranged on a substrate” means that the presence form of Ge and SiGe does not matter as long as Ge and SiGe are simultaneously present on the substrate. For example, Ge and SiGe may be in contact with each other or may be in contact with each other through another layer or member. In addition, there may be a form in which Ge and SiGe are not in contact with each other, although SiGe and Si are present on the same substrate.

The substrate is not particularly limited, and examples thereof include a metal substrate, a semiconductor substrate, a conductive substrate other than the metal substrate, a metal oxide substrate, a glass substrate, and a resin substrate. Among these, a semiconductor substrate is preferable.

Examples of the semiconductor substrate include a semiconductor wafer, a glass substrate for a photo mask, a glass substrate for liquid crystal display, a glass substrate for plasma display, a substrate for field emission display (FED), a substrate for an optical disk, a substrate for a magnetic disk, and a substrate for a magneto-optical disk.

Examples of a material constituting the semiconductor substrate include silicon, germanium, a III-V group compound such as GaAs, and a combination thereof.

Examples of the use of the element obtained by treating the object to be treated include a dynamic random access memory (DRAM), a ferroelectric random access memory (FRAM: registered trademark), a magnetoresistive random access memory (MRAM), a phase change random access memory (PRAM), a logic circuit, and a processor.

The form of Ge or SiGe on the substrate may be any form of film-like arrangement, wiring-like arrangement, plate-like arrangement, column-like arrangement, or particle-like arrangement.

The object to be treated may contain a layer and/or a structure as desired, in addition to Ge and SiGe.

For example, one or more members selected from the group consisting of a metal wire, a gate electrode, a source electrode, a drain electrode, an insulating layer, a ferromagnetic layer, and a non-magnetic layer may be disposed on the substrate.

The substrate may include an exposed integrated circuit structure.

Examples of the integrated circuit structure include an interconnection mechanism such as a metal wire and a dielectric material. Examples of metals and alloys used for the interconnection mechanism include aluminum, a copper-aluminum alloy, copper, nickel, nickel silicide, cobalt, cobalt silicide, ruthenium, platinum, gold, titanium, tantalum, tungsten, titanium nitride, and tantalum nitride. The substrate may include one or more layers of materials selected from the group consisting of silicon oxide, silicon nitride, silicon carbide, and carbon-doped silicon oxide.

### [Treatment Method]

The treatment method of an object to be treated according to the embodiment of the present invention (hereinafter, also referred to as “present treatment method”) includes a step A of bringing an object to be treated containing Ge and SiGe into contact with the above-described chemical liquid. Si in the object to be treated is selectively etched by performing the present treatment method.

The object to be treated used in the present treatment method is as described above.

Examples of the contact method include a method of immersing the object to be treated in the chemical liquid placed in a tank, a method of spraying the chemical liquid onto the object to be treated, a method of flowing the chemical liquid onto the object to be treated, and a method of combining these methods; and a method of immersing the object to be treated in the chemical liquid is preferable.

Furthermore, in order to further increase a treatment speed with the chemical liquid, a mechanical stirring method may be used.

Examples of the mechanical stirring method include a method of circulating the chemical liquid on the object to be treated, a method of passing or spraying the chemical liquid onto the object to be treated, and a method of stirring the chemical liquid with ultrasonic waves or megasonics.

A treatment time of the step A can be appropriately adjusted.

The treatment time (contact time between the chemical liquid and the object to be treated) is preferably 0.5 to 60 minutes and more preferably 1 to 20 minutes.

A temperature of the chemical liquid during the treatment is preferably 10° C. to 100° C. and more preferably 15° C. to 60° C.

### (Other Steps)

The present treatment method may include other steps in addition to the above-described step A.

Examples of the other steps include a step of forming each of one or more structures selected from the group consisting of a metal wire, a gate structure, a source structure, a drain structure, an insulating layer, a ferromagnetic layer, a non-magnetic layer, and the like (for example, layer formation, etching, chemical mechanical polishing, and modification); a step of forming resist, an exposure step, a removing step, a heat treatment step, a washing step, and an inspection step.

The present treatment method may be performed at any stage among the back-end process (BEOL: back end of the line), the middle process (MOL: middle of the line), and the front-end process (FEOL: front end of the line); and it is preferable that the present treatment method is performed in a front-end process or a middle process.

### Examples

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### <Preparation of Chemical Liquid>

A solvent and each component were mixed with the content shown in Table 1 later to obtain a mixed solution, and then the mixed solution was sufficiently stirred with a stirrer, thereby obtaining a chemical liquid used in each of Examples and Comparative Examples. More specifically, the solvent was put in a 250 mL beaker including a 1-inch stirrer coated with Teflon (registered trademark), and then each component other than the quinone compound was added thereto and mixed. Next, immediately before a treatment, the quinone compound was further added thereto and mixed, thereby obtaining the chemical liquid.

The content of the chemical liquid in Table 1 is based on mass, and the remainder of the total of the respective components is the solvent.

Abbreviations described in Table 1 later are as follows.

### [Quinone Compound]

p-BQ: p-benzoquinone
o-BQ: o-benzoquinone
NQ: 1,4-naphthoquinone
AQ: anthraquinone
mCPBA: meta-chloroperbenzoic acid

### [Halide Ion Source]

HF: 48% by mass hydrofluoric acid (aqueous solution containing 48% by mass of hydrogen fluoride with respect to the total mass of the solution)·
NH₄F: ammonium fluoride

### [Solvent]

EtOH: ethanol
EG: ethylene glycol
DMSO: dimethyl sulfoxide
THF: tetrahydrofuran
Water: ultrapure water
DMF: N,N-dimethylformamide
NMP: N-methylpyrrolidone
AcOEt: ethyl acetate

### <Evaluation>

A sample was treated with each chemical liquid according to the following procedure, and the evaluation was performed.

### [Removability]

First, a laminate in which a layer of SiGe(Si:Ge=75:25 (atomic number ratio)) was deposited on a germanium wafer so that the film thickness was 5 nm was obtained. A sample having a size of 2 cm×2 cm was cut out from the obtained laminate.

The sample was immersed in each chemical liquid (25° C.) for 10 minutes to perform a treatment. After the treatment, water was supplied to the surface of the sample at 500 mL/min for 30 seconds for washing, and the surface was dried by nitrogen blowing. After the drying, the surface of the sample was observed with scanning electron microscope-energy dispersive X-ray spectroscopy, and an area of SiGe residues observed within 1 μm² was calculated. Removability of the residue (SiGe) was evaluated according to the following evaluation standard, depending on the area of SiGe residues. Whether or not the residue was the SiGe residue was determined by detecting and analyzing characteristic X-rays of Si.

### (Evaluation Standard)

5: area of residues was 0.0001 μm² or less.
4: area of residues was more than 0.0001 μm² and 0.001 μm² or less.
3: area of residues was more than 0.001 μm² and 0.01 μm² or less.
2: area of residues was more than 0.01 μm² and 0.1 μm² or less.
1: area of residues was more than 0.1 μm².

### [Surface Roughness]

First, a sample having a size of 2 cm×2 cm was cut out from a germanium wafer.

The sample was immersed in each chemical liquid for treatment by the same method as the evaluation of the removability of residue, and then washed and dried.

The surface of the sample after the drying was observed with an atomic force microscope. As the atomic force microscope, NanoNavi Real manufactured by Hitachi High-Tech Corporation was used, in which the measurement mode was set to a contact mode, a cantilever SI-DF-40 manufactured by Hitachi, Ltd. was used, and observation was performed in a range of 1 μm square. From the observation results, a surface roughness (arithmetic average line roughness Ra) was obtained, and surface roughness of Ge was evaluated according to the following evaluation standard.

### (Evaluation Standard)

5: surface roughness was 0.10 nm or less.
4: surface roughness was more than 0.10 nm and 0.20 nm or less.
3: surface roughness was more than 0.20 nm and 0.30 nm or less.
2: surface roughness was more than 0.30 nm and 0.40 nm or less.
1: surface roughness was more than 0.40 nm.

### [Storage Stability]

First, a laminate in which a layer of SiGe(Si:Ge=75:25 (atomic number ratio)) was deposited on a germanium wafer so that the film thickness was 100 nm was obtained. A sample having a size of 2 cm×2 cm was cut out from the obtained laminate.

The sample was immersed in each chemical liquid for treatment by the same method as the evaluation of the removability of residue, and then washed and dried.

After the drying, a film thickness of the SiGe layer was measured with an optical film thickness meter (Ellipsometer M-2000, manufactured by J. A. Woollam Co., Ltd.), and a dissolution rate ER1 (Å/min) was calculated.

The same treatment and measurement of the film thickness were performed using each chemical liquid stored at 45° C. for 2 weeks after the preparation, using AIBOI wide-mouthed bottle (manufactured by AS ONE Corporation), and a dissolution rate ER2 (Å/min) was calculated. A ratio of ER2 to ER1 (ER2/ER1) was determined, and storage stability was evaluated according to the following evaluation standard.

### (Evaluation Standard)

5: ER2/ER1 was 0.9 or more.
4: ER2/ER1 was 0.8 or more and less than 0.9.
3: ER2/ER1 was 0.7 or more and less than 0.8.
2: ER2/ER1 was 0.6 or more and less than 0.7.
1: ER2/ER1 was less than 0.6.

### <Result>

The formulation of the chemical liquid and the evaluation results are shown in Table 1.

In Table 1, the content of each component in the chemical liquid is indicated by % by mass with respect to the total mass of the chemical liquid.

In a case where hydrofluoric acid was used as the halide ion source, the content of the hydrofluoric acid is indicated in the column of the amount of the halide ion source. In a case where hydrofluoric acid was used as the halide ion source, the content of hydrogen fluoride in the chemical liquid is a value obtained by multiplying the content of hydrofluoric acid by 0.48.

In Table 1, the column of “B/A” indicates the ratio of the content of the quinone compound to the content of the aromatic compound in the chemical liquid.

TABLE 1

| | | | Quinone | | Halide ion | | | | | | | |
|---|---|---|---|---|---|---|---|---|---|---|---|---|
| | Aromatic compound (A) | | compound (B) | | source | | | | | Evaluation | | |
| | | Amount | | Amount | | Amount | | | | | Surface | |
| | | [% by | | [% by | | [% by | Solvent | | | Remov- | rough- | Storage |
| | Type | mass] | Type | mass] | Type | mass] | Type | Amount | B/A | ability | ness | stability |
| Example 1 | Hydroquinone | 0.01 | p-BQ | 0.5 | HF | 1 | EtOH | Reminder | 50.0 | 5 | 5 | 5 |
| Example 2 | 1,4-Naphthalenedithiol | 0.01 | p-BQ | 0.5 | HF | 1 | EtOH | Reminder | 50.0 | 4 | 5 | 5 |
| Example 3 | 4-Hydroxybenzenethiol | 0.01 | p-BQ | 0.5 | HF | 1 | EtOH | Reminder | 50.0 | 4 | 5 | 5 |
| Example 4 | 1,4-Benzenedithiol | 0.01 | p-BQ | 0.5 | HF | 1 | EtOH | Reminder | 50.0 | 4 | 4 | 5 |
| Example 5 | 4- | 0.01 | p-BQ | 0.5 | HF | 1 | EtOH | Reminder | 50.0 | 3 | 4 | 4 |
| | (Methylthio)benzenethiol | | | | | | | | | | | |
| Example 6 | Hydroquinone | 0.005 | p-BQ | 0.5 | HF | 1 | EtOH | Reminder | 50.0 | 4 | 5 | 5 |
| | 1,4-Naphthalenedithiol | 0.005 | | | | | | | | | | |
| Example 7 | Hydroquinone | 0.0000001 | p-BQ | 0.5 | HF | 1 | EtOH | Reminder | 5000000.0 | 2 | 2 | 2 |
| Example 8 | Hydroquinone | 0.000001 | p-BQ | 0.5 | HF | 1 | EtOH | Reminder | 500000.0 | 3 | 3 | 3 |
| Example 9 | Hydroquinone | 0.8 | p-BQ | 0.5 | HF | 1 | EtOH | Reminder | 0.6 | 4 | 4 | 4 |
| Example 10 | Hydroquinone | 1.5 | p-BQ | 0.5 | HF | 1 | EtOH | Reminder | 0.3 | 2 | 2 | 2 |
| Example 11 | Hydroquinone | 0.01 | p-BQ | 0.5 | NH₄F | 1 | EtOH | Reminder | 50.0 | 4 | 4 | 5 |
| Example 12 | Hydroquinone | 0.01 | p-BQ | 0.5 | HF | 0.5 | EtOH | Reminder | 50.0 | 4 | 5 | 5 |
| | | | | | NH₄F | 0.5 | | | | | | |
| Example 13 | Hydroquinone | 0.01 | p-BQ | 0.5 | HF | 0.01 | EtOH | Reminder | 50.0 | 2 | 4 | 5 |
| Example 14 | Hydroquinone | 0.01 | p-BQ | 0.5 | HF | 0.05 | EtOH | Reminder | 50.0 | 3 | 5 | 5 |
| Example 15 | Hydroquinone | 0.01 | p-BQ | 0.5 | HF | 15 | EtOH | Reminder | 50.0 | 5 | 5 | 5 |
| Example 16 | Hydroquinone | 0.01 | p-BQ | 0.5 | HF | 30 | EtOH | Reminder | 50.0 | 5 | 3 | 5 |
| Example 17 | Hydroquinone | 0.01 | p-BQ | 0.09 | HF | 1 | EtOH | Reminder | 9.0 | 4 | 4 | 5 |
| Example 18 | Hydroquinone | 0.01 | p-BQ | 0.12 | HF | 1 | EtOH | Reminder | 12.0 | 5 | 5 | 5 |
| Example 19 | Hydroquinone | 0.01 | p-BQ | 1.8 | HF | 1 | EtOH | Reminder | 180.0 | 5 | 5 | 4 |
| Example 20 | Hydroquinone | 0.01 | p-BQ | 2.5 | HF | 1 | EtOH | Reminder | 250.0 | 5 | 3 | 3 |
| Example 21 | 1,5-Naphthalenedithiol | 0.01 | p-BQ | 0.5 | HF | 1 | EtOH | Reminder | 50.0 | 3 | 3 | 4 |
| Example 22 | Catechol | 0.01 | p-BQ | 0.5 | HF | 1 | EtOH | Reminder | 50.0 | 3 | 3 | 4 |
| Example 23 | Hydroquinone | 0.01 | p-BQ | 0.5 | HF | 1 | EG | Reminder | 50.0 | 5 | 5 | 5 |
| Example 24 | Hydroquinone | 0.01 | p-BQ | 0.5 | HF | 1 | DMSO | Reminder | 50.0 | 5 | 5 | 5 |
| Example 25 | Hydroquinone | 0.01 | p-BQ | 0.5 | HF | 1 | THF | Reminder | 50.0 | 5 | 5 | 5 |
| Example 26 | Hydroquinone | 0.01 | p-BQ | 0.5 | HF | 1 | Water | Reminder | 50.0 | 5 | 5 | 5 |
| Example 27 | Hydroquinone | 0.01 | p-BQ | 0.5 | HF | 1 | DMF | Reminder | 50.0 | 4 | 5 | 4 |
| Example 28 | Hydroquinone | 0.01 | p-BQ | 0.5 | HF | 1 | NMP | Reminder | 50.0 | 4 | 5 | 4 |
| Example 29 | Hydroquinone | 0.01 | p-BQ | 0.5 | HF | 1 | AcOEt | Reminder | 50.0 | 4 | 5 | 4 |
| Example 30 | Hydroquinone | 0.01 | p-BQ | 0.5 | HF | 1 | EtOH | Reminder | 50.0 | 5 | 5 | 5 |
| | | | | | | | EG | (1:1) | | | | |
| Example 31 | 2,3-Dihydroxypyridine | 0.01 | p-BQ | 0.5 | HF | 1 | EtOH | Reminder | 50.0 | 2 | 3 | 3 |
| Example 32 | 1,4-Benzenediselenol | 0.01 | p-BQ | 0.5 | HF | 1 | EtOH | Reminder | 50.0 | 2 | 3 | 3 |
| Example 33 | Hydroquinone | 0.01 | o-BQ | 0.5 | HF | 1 | EtOH | Reminder | 50.0 | 5 | 5 | 5 |
| Example 34 | Hydroquinone | 0.01 | NQ | 0.5 | HF | 1 | EtOH | Reminder | 50.0 | 4 | 5 | 5 |
| Example 35 | Hydroquinone | 0.01 | AQ | 0.5 | HF | 1 | EtOH | Reminder | 50.0 | 3 | 5 | 5 |
| Example 36 | Hydroquinone | 0.01 | p-BQ | 0.25 | HF | 1 | EtOH | Reminder | 50.0 | 4 | 5 | 5 |
| | | | NQ | 0.25 | | | | | | | | |
| Example 37 | Leucoquinizarin | 0.01 | p-BQ | 0.5 | HF | 1 | EtOH | Reminder | 50.0 | 4 | 5 | 5 |
| Comparative | Phenol | 0.01 | p-BQ | 0.5 | HF | 0.5 | EtOH | Reminder | 50.0 | 1 | 2 | 1 |
| Example 1 | | | | | | | | | | | | |
| Comparative | p-Phenylenediamine | 0.01 | p-BQ | 0.5 | HF | 0.5 | EtOH | Reminder | 50.0 | 1 | 1 | 1 |
| Example 2 | | | | | | | | | | | | |
| Comparative | p-Xylene glycol | 0.01 | p-BQ | 0.5 | HF | 0.5 | EtOH | Reminder | 50.0 | 1 | 1 | 1 |
| Example 3 | | | | | | | | | | | | |
| Comparative | Hydroquinone | 0.01 | mCPBA | 0.5 | HF | 1 | EtOH | Reminder | 50.0 | 1 | 1 | 2 |
| Example 4 | | | | | | | | | | | | |
| Comparative | Hydroquinone | 0.01 | p-BQ | 0.5 | — | 0 | EtOH | Reminder | 50.0 | 1 | 1 | 2 |
| Example 5 | | | | | | | | | | | | |

From the results in Table 1, it was found that the chemical liquid according to the embodiment of the present invention had excellent removability of SiGe and excellent suppression of surface roughness of Ge. In a case where the chemical liquid according to the embodiment of the present invention was applied to an object to be treated containing Ge and SiGe, it can be said that the removability of SiGe is excellent and the surface roughness of Ge is suppressed.

On the other hand, in the chemical liquids of Comparative Examples 1 to 3, containing a compound which is not the above-described aromatic compound represented by Formula (1), in the chemical liquid of Comparative Example 4, not containing the quinone compound, and in the chemical liquid of Comparative Example 5, not containing the halide ion source, at least one of the removability of SiGe or the surface roughness of Ge was deteriorated.

From the comparison between Example 8 and Example 7, and the comparison between Example 10 and Example 9, it was found that, in a case where the content of the aromatic compound was 5 ppb by mass to 1% by mass with respect to the total mass of the chemical liquid, the removability, the evaluation of the surface roughness, and the storage stability were excellent.

From the comparison between Example 31 and Examples 1, 2, and 37, it was found that, in a case where Ar in Formula (1) represented a benzene ring, a naphthalene ring, or an anthracene ring, the removability, the evaluation of the surface roughness, and the storage stability were excellent.

From the comparison between Example 22 and Example 1, the comparison between Example 21 and Example 2, and the comparison between Example 5 and Example 4, it was found that, in a case where any one of the above-described requirements 1 to 4 was satisfied, the removability, the evaluation of the surface roughness, and the storage stability were excellent.

From the comparison between Example 32 and Examples 1, 3, and 4, it was found that, in a case where X's in Formula (1) were each an oxygen atom or a sulfur atom, the removability, the evaluation of the surface roughness, and the storage stability were excellent.

From the comparison between Examples 2 and 3 and Example 1, it was found that, in a case where X₁ and X₂ in Formula (2) each represented an oxygen atom and R₃ and R₄ each represented a hydrogen atom, the removability, the evaluation of the surface roughness, and the storage stability were excellent.

From the comparison between Example 11 and Example 1, it was found that, in a case where the halide ion source included hydrogen fluoride, the removability, the evaluation of the surface roughness, and the storage stability were excellent.

From the comparison between Example 13 and Example 14, and the comparison between Example 16 and Example 15, it was found that, in a case where the content of hydrogen fluoride was 0.01% to 10% by mass with respect to the total mass of the chemical liquid, the evaluation of the surface roughness was excellent.

From the comparison between Example 17 and Example 18, and the comparison between Example 20 and Example 19, it was found that, in a case where the ratio of the content of the quinone compound to the content of the aromatic compound was 10.0 to 200.0, the evaluation of the surface roughness was excellent.

What is claimed is:

1. A chemical liquid comprising:
an aromatic compound represented by Formula (1);
a quinone compound having a quinone structure;
a halide ion source; and
a solvent, 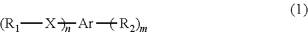
in Formula (1), Ar represents an aromatic ring,
X's each independently represent a Group 16 element and R₁'s each independently represent a hydrogen atom or a substituent, n represents an integer of 2 or more,
R₂'s each independently represent a substituent, and m represents an integer of 0 or more.

2. The chemical liquid according to claim 1,
wherein a content of the aromatic compound is 5 ppb by mass to 1% by mass with respect to a total mass of the chemical liquid.

3. The chemical liquid according to claim 1,
wherein Ar in Formula (1) is a benzene ring, a naphthalene ring, or an anthracene ring.

4. The chemical liquid according to claim 2,
wherein Ar in Formula (1) is a benzene ring, a naphthalene ring, or an anthracene ring.

5. The chemical liquid according to claim 3,
wherein any one of the following requirements 1 to 4 is satisfied,
requirement 1: n in Formula (1) is 2, R₁ represents a hydrogen atom, Ar in Formula (1) represents a benzene ring, and bonding positions of two groups represented by —X—R₁ are a 1-position and a 4-position of the benzene ring,
requirement 2: n in Formula (1) is 2, R₁ represents a hydrogen atom, Ar in Formula (1) represents a naphthalene ring, and bonding positions of two groups represented by —X—R₁ are a 1-position and a 4-position of the naphthalene ring,
requirement 3: n in Formula (1) is 2, Ar in Formula (1) represents an anthracene ring, and bonding positions of two groups represented by —X—R₁ are a 9-position and a 10-position of the anthracene ring,
requirement 4: n in Formula (1) is 4, Ar in Formula (1) represents an anthracene ring, and bonding positions of four groups represented by —X—R₁ are a 1-position, a 4-position, a 9-position, and a 10-position of the anthracene ring.

6. The chemical liquid according to claim 1,
wherein X's in Formula (1) are each independently an oxygen atom or a sulfur atom.

7. The chemical liquid according to claim 2,
wherein X's in Formula (1) are each independently an oxygen atom or a sulfur atom.

8. The chemical liquid according to claim 1,
wherein the aromatic compound is a compound represented by Formula (2), 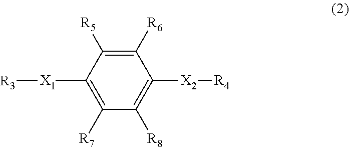
in Formula (2), R₃ and R₄ each independently represent a hydrogen atom or an alkyl group,
X₁ and X₂ each independently represent a Group 16 element,
R₅ to R₈ each independently represent a hydrogen atom or a substituent, and
the substituent represented by R₅ and R₆ and the substituent represented by R₇ and R₈ may be bonded to each other to form a ring.

9. The chemical liquid according to claim 2,
wherein the aromatic compound is a compound represented by Formula (2), 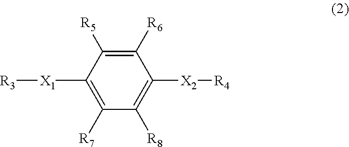
in Formula (2), R₃ and R₄ each independently represent a hydrogen atom or an alkyl group,
X₁ and X₂ each independently represent a Group 16 element,
R₅ to R₈ each independently represent a hydrogen atom or a substituent, and
the substituent represented by R₅ and R₆ and the substituent represented by R₇ and R₈ may be bonded to each other to form a ring.

10. The chemical liquid according to claim 8,
wherein, in Formula (2), X₁ and X₂ represent oxygen atoms and R₃ and R₄ represent hydrogen atoms.

11. The chemical liquid according to claim 1,
wherein the halide ion source includes hydrogen fluoride.

12. The chemical liquid according to claim 2,
wherein the halide ion source includes hydrogen fluoride.

13. The chemical liquid according to claim 11,
wherein a content of the hydrogen fluoride is 0.01% to 10% by mass with respect to a total mass of the chemical liquid.

14. The chemical liquid according to claim 1,
wherein a ratio of a content of the quinone compound to a content of the aromatic compound is 10.0 to 200.0.

15. The chemical liquid according to claim 2,
wherein a ratio of a content of the quinone compound to a content of the aromatic compound is 10.0 to 200.0.

16. The chemical liquid according to claim 1,
wherein the solvent includes one or more solvents selected from the group consisting of water, an alcohol solvent, an ether solvent, an ester solvent, an amide solvent, and a sulfoxide solvent.

17. The chemical liquid according to claim 2,
wherein the solvent includes one or more solvents selected from the group consisting of water, an alcohol solvent, an ether solvent, an ester solvent, an amide solvent, and a sulfoxide solvent.

18. The chemical liquid according to claim 1,
wherein the chemical liquid is applied to an object to be treated containing germanium and silicon-germanium.

19. The chemical liquid according to claim 2,
wherein the chemical liquid is applied to an object to be treated containing germanium and silicon-germanium.

20. A treatment method of an object to be treated, comprising:
a step of bringing the chemical liquid according to claim 1 into contact with an object to be treated containing germanium and silicon-germanium.
